(19) United States
(12) Patent Application Publication
(10) Pub. No.: US 2018/0306855 A1
(43) Pub. Date: Oct. 25, 2018

(54) DEVICE FOR DETECTION OF A FAULTY FUNCTION OF A PLANAR OLED LIGHT SOURCE OR A GROUP OF OLED LIGHT SOURCES, ESPECIALLY FOR A HEADLIGHT OR A LAMP OF A MOTOR VEHICLE

(71) Applicant: Varroc Lighting Systems, s.r.o., Senov u Noveho Jicina (CZ)

(72) Inventors: Tomas Gloss, Vitkov (CZ); Petr Novak, Senov u Noveho Jicina (CZ); Ludek Mazal, Tisek (CZ)

(21) Appl. No.: 15/951,843

(22) Filed: Apr. 12, 2018

(30) Foreign Application Priority Data
Apr. 19, 2017 (CZ) PV 2017-212

(51) Int. Cl. G01R 31/26; H01L 51/52; H05B 33/08; F21S 41/141; G01R 31/28

(52) U.S. Cl. CPC G01R 31/2635; H01L 51/52; G01R 31/2874; F21S 41/141; H05B 33/0803

(57) ABSTRACT

The device for detecting a faulty function of a planar OLED light source or group thereof, comprises a main connector for supplying input voltage to the control unit adapted to receive information from the detector, and to control the voltage- or current-generating power supply unit for the measured OLED light source(s) via a sensing unit measuring the course of the V-A characteristic and/or certain evaluation point(s) thereof of the measured OLED source(s), and connected to a detector for evaluation whether the measured OLED source(s) exhibits a faulty function, and communication of the evaluated data to the control unit. It further comprises a temperature sensor to measure the temperature of the OLED source(s) and/or of their environment, the detector configured so that to evaluate whether the measured OLED source(s) exhibits a faulty function, the known course or certain evaluation point(s) of the V-A characteristic of a faultless OLED source is compared to established values of the measured OLED source(s), accounting for the measured temperature.

A device for detection of a faulty function of a planar OLED light source or a group of OLED light sources, especially for a headlight or a lamp of a motor vehicle.

### FIELD OF THE INVENTION

The invention relates to a device for detection of a faulty function of a planar OLED light source or a group of OLED sources, especially for a headlight or lamp of a motor vehicle that uses a check system evaluating the V-A characteristic of OLED's to detect a faulty light source.

### BACKGROUND INFORMATION

New vehicle lighting systems do not only focus on the optical output increasing the driving comfort and traffic safety, but it is also the appearance that is important for modern light devices of motor vehicles as headlights or signal lamps of a motor vehicles. Modern point and planar light sources, especially LED and OLED sources, have opened a new chapter for new stylistic options of car designers.

Using a planar light source, especially OLED—Organic Light Emitting Diodes—brings not only an extension of designer possibilities of the emitted light function, but it is also characterized by certain technical benefits, such as, e.g., compact installation dimensions, low heat production, low energy consumption, etc. Consequently, the use of OLED's is gradually becoming more complex and complicated while all specifications and legal requirements, especially in the automotive industry, must be observed. One of the requirements is detection of a faulty status of a light source. With conventional LED's, this condition can be detected relatively well because in most cases, a short circuit or diode disconnection occurs, which results in a change of an electric quantity that can be relatively easily electronically detected. The situation of planar sources is more complicated because an OLED does not comprise a conventional PN transition, but organic layers that emit light after connection of electric voltage/current.

Unlike conventional LED's, where the size/area of the PN transition is on the order of single mm2 at the most, concerning OLED's a situation might occur that a local defect, i.e. dark or conversely very light areas, is formed. In this state, the diode is neither disconnected nor short-circuited, which makes detection and evaluation of this state as faulty difficult. The situation is also complicated by the fact that as the ambient temperature changes, the voltage on the OLED changes, and this voltage also changes in the course of OLED ageing. Another possible defect/fault is the state when an OLED does not work at all and does not emit light from any part of this surface.

In the documents KR20130031116A, WO2012007968A1, WO2010060458A1, GB2405272B, US20050179393A1, US20040080273A1 U.S. Pat. No. 6,417,624B1, a great number of solutions can be found that make it possible to detect a faulty state of a planar light source. A substantial disadvantage of the solutions described above is the fact that the detection system of a faulty function of planar light sources does not comprise temperature measurement while the properties of OLED's from the point of view of the V-A characteristic principally change as the temperature changes. Especially, as the ambient temperature changes, the OLED voltage changes as well, while this voltage also changes during ageing of the OLED.

The object of the invention is to provide a new design of a device for detection of faults of planar light sources, especially for a headlight or lamp of a motor vehicle that will be able to measure the V-A characteristic or a parameter of the V-A characteristic, the device comprising a system of temperature measurement in the vicinity of the OLED or of the OLED itself. During the detection, the measured data must be compared to data stored in a memory or to the settings of a temperature-controlled comparator. The measured data must be subsequently evaluated so as to avoid wrong detection of a functional, damaged, partly damaged or faulty OLED.

### SUMMARY OF THE INVENTION

The above mentioned object of the invention is fulfilled by a device for detection of a faulty function of a planar OLED light source or a group of OLED light sources, especially for a headlight of a lamp of a motor vehicle according to the invention, comprising as the input electric interface the main connector for the supply of the input voltage to the control unit, which is adapted to receive information from the detector, and to control the voltage- or current-generating power supply unit for the measured OLED light source or group or OLED light sources connected to the power supply unit via a sensing unit that is adapted to measure the course of the V-A characteristic and/or a certain evaluation point or points of the V-A characteristic of the measured OLED source or group of OLED sources, and connected to a detector for evaluation whether the measured OLED source or group of OLED sources exhibits a faulty function, the detector being adapted to communicate the evaluated data to the control unit. The device further comprises a temperature sensor to measure the temperature of the OLED source or group of OLED sources and/or the temperature in their environment, the detector being configured in such a way that to evaluate whether the measured OLED source or group of OLED sources exhibits a faulty function, the known course or certain evaluation point/points of the V-A characteristic of a faultless OLED source or group of OLED sources is compared to the established values of the measured OLED source or group of OLED sources, taking into account the influence of the temperature measured by the temperature sensor.

In one of the embodiments, the detector is designed as a temperature-controlled comparator adapted to measure and evaluate the course or an evaluation point of the V-A characteristic and the temperature of the OLED source or group of OLED sources and/or the temperature in their environment.

In one of the embodiments, for detection of a completely non-functioning OLED source, the power supply unit works in the 1.0 V to 5.0 V low-voltage mode and/or a special voltage source is connected in parallel to the power supply unit between the control unit and the sensing unit to produce independent low voltage from 1.0 V to 5.0 V while this low voltage is supplied to the measured OLED source, and the detector is configured to evaluate whether the measured OLED source is entirely non-functional based on assessment of the current passing through the OLED source at this low voltage.

The special voltage source can be configured as a controllable/switchable linear or DC/DC OLED driver/power supply.

In one of the embodiments, the detector is arranged within the processor unit, e.g. a microcontroller or microprocessor.

The processor unit can comprise an A/D converter.

The processor unit can comprise a memory to save the original known V-A characteristic of a faultless OLED source in relation to a certain temperature of this OLED source or its environment.

### DESCRIPTION OF DRAWINGS

The present invention will be further clarified in more detail with the use of embodiment examples referring to the enclosed drawings where:

FIG. 1 shows a block diagram of the first embodiment example of the device for detection of a faulty function of a planar OLED light source or a group of OLED light sources, especially for a headlight of a lamp of a motor vehicle according to the invention,

FIG. 2 shows a block diagram of the second embodiment example of the device for detection of a faulty function of a planar OLED light source or a group of OLED light sources,

FIG. 3 shows a block diagram of the third embodiment example of the device for detection of a faulty function of a planar OLED light source or a group of OLED light sources, and

FIG. 4 shows an example of the A-V characteristic of an OLED source in a faultless state.

### DETAILED DESCRIPTION OF THE INVENTION

For the purposes of this invention, a faulty OLED source is represented by a state when the source exhibits a faulty function. An example of a faulty OLED source is a damaged source. An OLED source may even be faulty to such an extent that it is completely non-functional. A source that does not exhibit a faulty function is a faultless source.

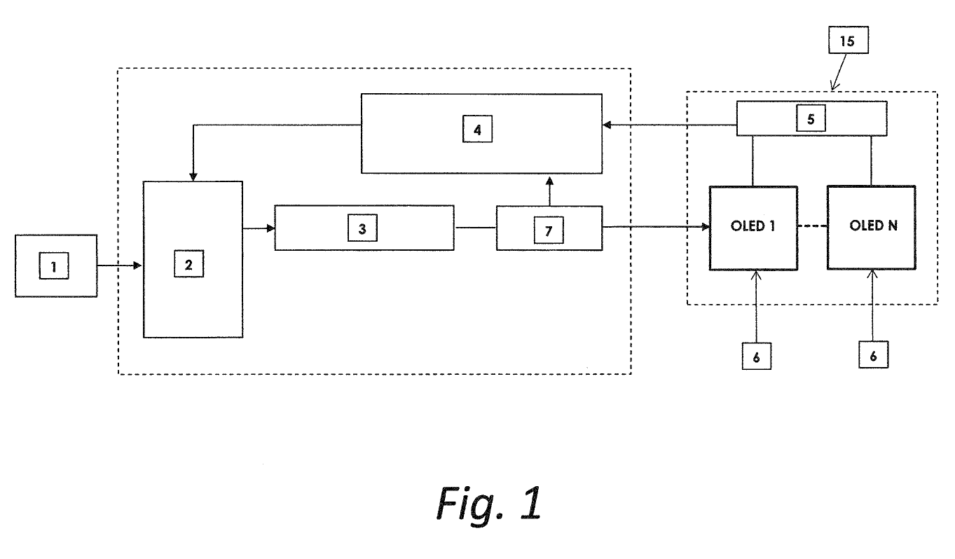

Now, the first embodiment example of the invention will be described with reference to the attached FIG. 1. FIG. 1 shows a block diagram of the proposed connection architecture of individual components of the device for detection of faults of planar OLED light sources in accordance with the invention. The block diagram consists of the following elements: the main connector 1 to supply the input voltage to the control unit 2, which is adapted to receive information from the detector 4 and to control the power supply unit 3. The power supply unit 3 generates voltage or current, so it can be of a voltage or current type. The OLED source 6 is connected to the power supply unit 3 via a sensing unit 7, which is adapted to measure the, here not shown, course 12 of the V-A characteristic and/or a certain evaluation point 13 of the V-A characteristic. The sensing unit 7 is connected to a detector 4 used to evaluate whether an OLED source 6 is faulty. The detector 4 is adapted to output the evaluated data to the control unit 2 and is connected to a temperature sensor 5. A part of the electronic circuit is a temperature sensor 5 adapted to measure the temperature of an OLED source or group of OLED sources 6 and/or the temperature in its/their (surrounding) environment 15 (neighborhood). The detector 4 is implemented e.g. in the form of a temperature-controlled comparator adapted to measure and evaluate the measured data, especially the V-A characteristic or the given voltage and current, respectively, related to the temperature of the OLED source 6 or the temperature of the environment 15 of the OLED 6.

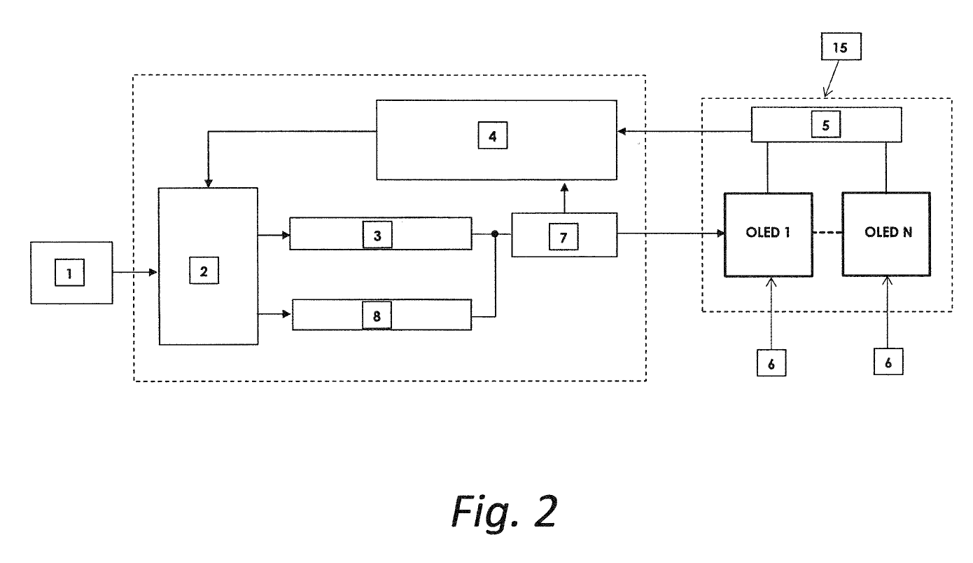

FIG. 2 shows a block diagram of the second embodiment of the connection architecture of individual components where between the control unit 2 and sensing unit 7 of the V-A characteristic a source 8 of special voltage is connected in parallel to the power supply unit 3, the source of special voltage being controlled by the control unit 2 to produce sufficient voltage. The source 8 of special voltage is implemented, e.g., as a controllable/switchable linear or DC/DC OLED driver/power supply unit or as an entirely independent voltage source.

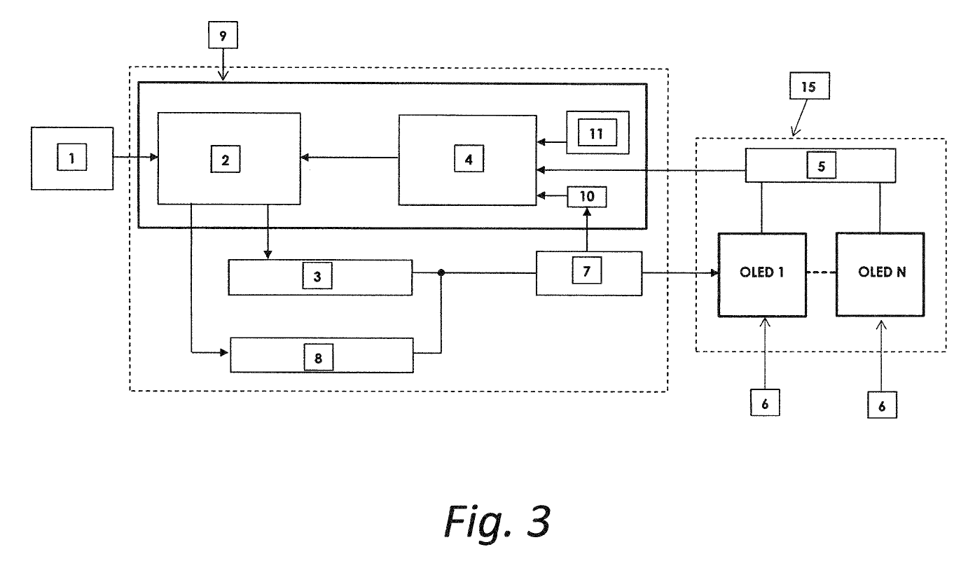

According to the embodiment example shown in FIG. 3, the control unit 2 and detector 4 are implemented through a processor unit 9, e.g. a microcontroller or microprocessor, comprising an A/D converter 10 and memory 11, e.g. EEPROM or FLASH. The memory 11 is used to save the original V-A characteristic corresponding to a new, faultless OLED source 6 related to a certain temperature of the OLED source 6 or the environment 15 of the OLED source 6, or also the wear related to ageing. The processor unit 9 compares the measured values to the original data of the V-A characteristic saved in the memory 11.

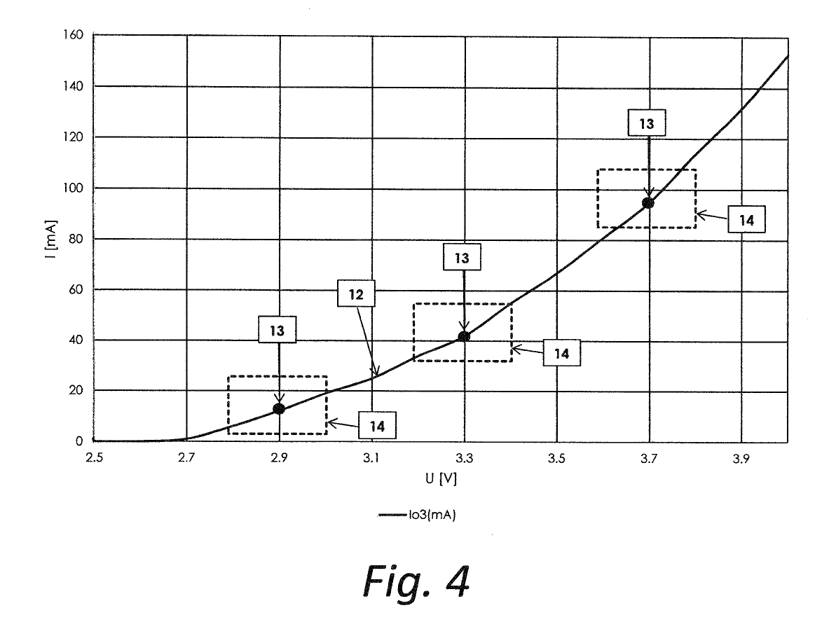

FIG. 4 shows an example of the course 12 of the V-A characteristic where a tolerance band 14 is assigned to certain evaluation points 13 of the V-A characteristic measured with a faultless OLED source and at a certain temperature.

After connection of the electric power supply to the OLED source 6, light is emitted and the sensing unit 7 measures the V-A characteristic or just one of the parameters of the V-A characteristic, e.g. voltage or current. The temperature sensor 5 measures the temperature of the OLED source 6 and/or the temperature of the environment 15 of the OLED source 6. The measurement can be conducted for one OLED source 6 or for the general function of several OLED sources 6, or each OLED source 6 may have its own temperature sensor 5. Subsequently, the measured data, i.e. the course 12 of the given V-A characteristic or just an evaluation point 13 having a certain given voltage, current and temperature value, are compared to the original data saved in the memory 11 related to a certain evaluation point 13 or course 12 of the originally measured V-A characteristic and the temperature of a faultless OLED source 6. If the voltage and current of the evaluation point 13 or the general course 12 of the V-A characteristic is not within the tolerance band 14, the detector 4 will assess the function as faulty and send/output this information to the control unit 2 while this measurement can be conducted during movement of the vehicle. Detection of an entirely non-functional OLED source 6 is conducted either by means of the power supply unit 3 operating in the 1.0 V-5.0 V low voltage mode, or the source 8 of special voltage in the voltage range of 1.0-5.0 V, while the detector 4 measures/evaluates the minimum current that can still pass through the OLED source 6 at this voltage. The detection principle is that if higher than the minimum permissible current passes through the OLED 6 at this low voltage already, OLED 6 is faulty.

### LIST OF REFERENCE MARKS

1—main connector
2—control unit
3—power supply unit
4—detector
5—temperature sensor
6—OLED source
7—sensing unit
8—source of special voltage
9—processor unit
10—A/D converter
11—memory
12—course
13—evaluation point
14—tolerance band
15—environment

1. A device for detection of a faulty function of a planar OLED light source or a group of OLED light sources, for example for a motor vehicle headlight or a lamp, comprising as an input electric interface a main connector (1) for the supply of the input voltage to a control unit (2), which control unit (2) is adapted to receive information from a detector (4) and to control a voltage- or current-generating power supply unit (3) for the measured OLED light source or group or OLED light sources (6) connected to the power supply unit (3) via a sensing unit (7), which sensing unit (7) is adapted to measure the course (12) of the V-A characteristic and/or a certain evaluation point (13) or points (13) of the V-A characteristic of the measured OLED source or group of OLED sources (6), and is connected to the detector (4) for evaluation whether the measured OLED source or group of OLED sources (6) exhibits a faulty function, the detector (4) being adapted to communicate the evaluated data to the control unit (2), wherein the device comprises a temperature sensor (5) to measure the temperature of the OLED source or group of OLED sources (6) and/or the temperature in their environment (15), the detector (4) being configured in such a way that to evaluate whether the measured OLED source or group of OLED sources (6) exhibits a faulty function, known course or certain evaluation point/points of the V-A characteristic of a faultless OLED source or group of OLED sources is compared to established values of the measured OLED source or group of OLED sources (6), taking into account the influence of temperature measured by the temperature sensor (5).

2. The device in accordance with claim 1, wherein the detector (4) is designed as a temperature-controlled comparator adapted to measure and evaluate the course (12) or an evaluation point (13) of the V-A characteristic and the temperature of the OLED source or group of OLED sources (6) and/or the temperature in their environment (15).

3. The device in accordance with claim 1, wherein for detection of a completely non-functioning OLED source (6), the power supply unit (3) works in the 1.0 V to 5.0 V low-voltage mode and/or a special voltage source (8) is connected in parallel to the power supply unit (3) between the control unit (2) and the sensing unit (7) to produce independent low voltage from 1.0 V to 5.0 V, while this low voltage is supplied to the measured OLED source (6) and the detector (4) is configured to evaluate whether the measured OLED source (6) is entirely non-functional based on assessment of the current passing through the OLED source (6) at this low voltage.

4. The device in accordance with claim 3, wherein the special voltage source (8) is configured as a controllable/switchable linear or DC/DC OLED driver/power supply.

5. The device in accordance with claim 1, wherein the detector (4) is arranged within a processor unit (9), which can comprise a microcontroller or a microprocessor.

6. The device in accordance with claim 5, characterized in that the processor unit (9) comprises an A/D converter (10).

7. The device in accordance with claim 5, wherein the processor unit (9) comprises a memory (11) to save original known V-A characteristics of a faultless OLED source (6) in relation to a certain temperature of this OLED source (6) or its environment (15).
